(19) United States
(12) Patent Application Publication
(10) Pub. No.: US 2020/0066516 A1
(43) Pub. Date: Feb. 27, 2020

(54) Semiconductor Structures Which Include Laminates of First and Second Regions, and Methods of Forming Semiconductor Structures

(71) Applicant: Micron Technology, Inc., Boise, ID (US)

(72) Inventors: Manuj Nahar, Boise, ID (US); Darwin Franseda Fan, Boise, ID (US)

(73) Assignee: Micron Technology, Inc., Boise, ID (US)

(21) Appl. No.: 16/112,372

(22) Filed: Aug. 24, 2018

(51) Int. Cl. H01L 21/02; H01L 21/306; H01L 29/165; H01L 29/78; H01L 29/06; H01L 29/10; H01L 27/108; C30B 25/18; C30B 29/06; C30B 29/08

(52) U.S. Cl. CPC H01L 21/02587; C30B 29/08; H01L 21/0245; H01L 21/0262; H01L 21/30604; H01L 21/02598; H01L 21/02595; H01L 29/165; H01L 29/7827; H01L 29/0684; H01L 29/1054; H01L 27/10805; C30B 25/18; C30B 29/06; H01L 21/02532

(57) ABSTRACT

Some embodiments include a semiconductor structure having a laminate which has first regions alternating with second regions. The first regions include silicon, and the second regions include germanium. Some embodiments include a method of forming a semiconductor structure. The semiconductor structure may correspond to at least a portion of an active region of a transistor. A first semiconductor material is deposited with a first deposition process. The first semiconductor material includes silicon. The first deposition process is intermittently interrupted to etch a surface of the deposited first semiconductor material and to deposit a second semiconductor material with a second deposition process. The second semiconductor material includes germanium. The semiconductor structure is at least partially crystalline.

### TECHNICAL FIELD

Semiconductor structures which include laminates of first and second regions, and methods of forming semiconductor structures.

### BACKGROUND

Transistors may be utilized in numerous applications; such as, for example, dynamic random-access memory (DRAM), resistive RAM (RRAM), magnetic RAM (MRAM), spin-transfer-torque-MRAM (STT-MRAM), etc.

A field-effect transistor (FET) comprises an active region. The active region includes a gated channel region between a pair of source/drain regions.

A continuing goal of semiconductor fabrication is to increase the density of integration. It is therefore desired to develop improved FET architectures which are suitable for utilization in highly-integrated architectures, and to develop methods for fabricating such FET architectures.

Vertical transistors are transistors in which a channel region extends vertically between source/drain regions. Vertical transistors may be utilized as access devices in highly-integrated memory architectures.

It is desirable to include crystalline semiconductor materials within transistor active regions. Crystalline semiconductor materials may be readily formed with thermal processing utilizing temperatures in excess of 600° C. However, transistors may be formed after other integrated components. Such other integrated components may be adversely impacted by the high temperatures utilized to form the crystalline semiconductor materials.

Efforts have been made to develop methods suitable for epitaxially forming crystalline semiconductor materials at temperatures below 600° C. However, conventional approaches generally form semiconductor materials which transition from crystalline to amorphous beyond a certain thickness (referred to as the critical epitaxial thickness), and thus are limited to fabrication of thin crystalline materials. The phenomenon of critical epitaxial thickness may be exaggerated (i.e., particularly problematic) for semiconductor materials comprising polycrystalline material It would be desirable to develop low-temperature methods for fabricating crystalline semiconductor materials which have larger critical epitaxial thickness than conventional methods, and which preferably may form the crystalline semiconductor materials (e.g., materials comprising polycrystalline silicon) to any desired thickness (i.e., which are not limited by a critical epitaxial thickness).

### BRIEF DESCRIPTION OF THE DRAWINGS

FIG. 1 shows diagrammatic cross-sectional views of an example structure at example process stages of an example method.

FIGS. 2 and 3 are diagrammatic cross-sectional views of example structures.

FIG. 4 shows diagrammatic cross-sectional views of an example structure at example process stages of an example method.

FIG. 5 shows diagrammatic cross-sectional views of an example structure at example process stages of an example method.

FIG. 6 shows a schematic view of a region of an example memory array.

FIG. 7 shows diagrammatic cross-sectional views of an example structure at example process stages of an example method.

FIG. 8 shows diagrammatic cross-sectional views of an example structure at example process stages of an example method.

### DETAILED DESCRIPTION OF THE ILLUSTRATED EMBODIMENTS

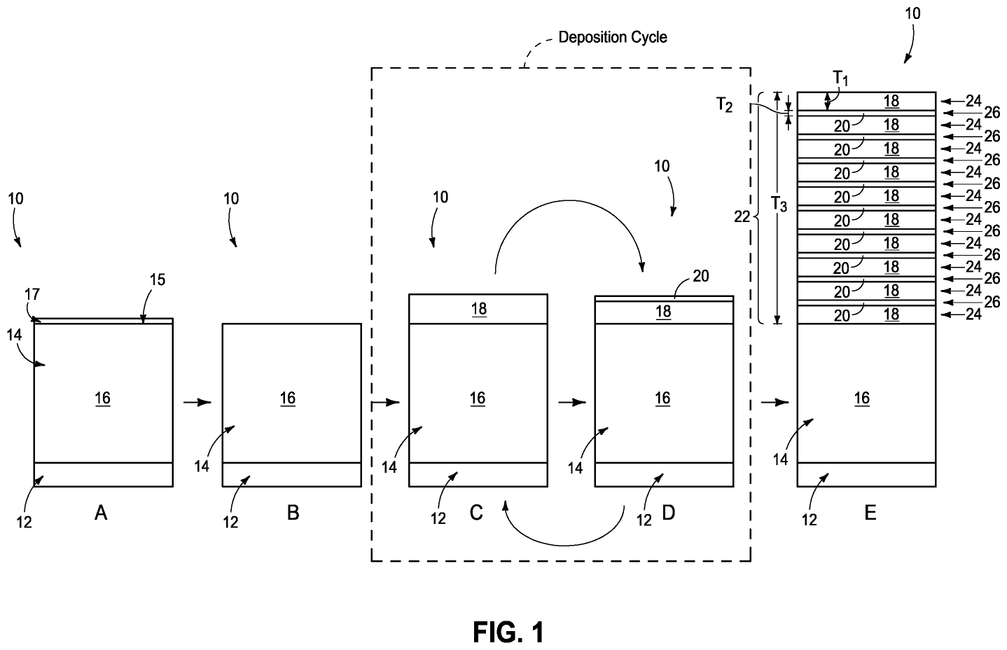

Some embodiments include methods suitable to form semiconductor materials. The semiconductor materials may be at least partially crystalline, and may have two or more different semiconductor compositions dispersed therethrough (e.g., may have germanium-containing regions alternating with regions consisting essentially of silicon). The semiconductor materials may be formed at low temperatures (e.g., temperatures of less than or equal to about 550° C.) in some embodiments, and may be formed to any desired thickness (i.e., may be unconstrained by a critical epitaxial thickness). The semiconductor materials may be incorporated into transistor active regions, or may be utilized in any other suitable applications. Example methods are described below with reference to FIGS. 1-8.

Referring to FIG. 1, a portion of a construction 10 includes a template 14 supported by a base 12. The construction 10 is shown at a process stage “A” at the left side of FIG. 1.

The base 12 may comprise semiconductor material; and may, for example, comprise, consist essentially of, or consist of monocrystalline silicon. The base 12 may be referred to as a semiconductor substrate. The term “semiconductor substrate” means any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductor substrates described above. In some applications, the base 12 may correspond to a semiconductor substrate containing one or more materials associated with integrated circuit fabrication. Such materials may include, for example, one or more of refractory metal materials, barrier materials, diffusion materials, insulator materials, etc.

The template 14 may be over and directly against any suitable material of the base 12; and in some applications may be over and directly against a semiconductor material of the base 12, an insulative material of the base 12, or a conductive material of the base 12.

The template 14 comprises a surface 15. In some embodiments, the surface 15 may be a surface of a crystalline material, and may be utilized as a seed for growing crystalline semiconductor structures over the template. In some embodiments, the crystalline material may be polycrystalline, and in some embodiments the crystalline material may be monocrystalline. The template 14 may comprise any suitable composition(s). In some embodiments, the template comprises semiconductor material 16; and such semiconductor material may comprise, consist essentially of, or consist of one or both of silicon and germanium.

The crystalline material of the template is preferably formed at relatively low temperature in order to avoid or eliminate the problems described above in the “Background” section (e.g., in order to avoid or eliminate problems of thermally degrading integrated circuitry which may be associated with the base 12). The term “relatively low temperature” refers to a temperature below the 600° C. temperature associated with conventional processes. In some embodiments, the crystalline material of the template 14 may be formed at a temperature of less than or equal to about 550° C.

If the template 14 comprises silicon in the absence of germanium, it may be desirable for the template 14 to be heavily-doped (i.e., to be doped to a concentration of at least about 10²¹ atoms/cm³ with conductivity-enhancing dopant) so that the crystalline material of the template may be formed at the desired relatively low temperature. The conductivity-enhancing dopant may be n-type (e.g., phosphorus) or p-type (e.g., boron).

If the template 14 comprises germanium in addition to silicon (e.g., comprises SiGe, with the formula indicating primary constituents rather than a specific stoichiometry), then the relative amount of germanium may be chosen to tailor the temperature for fabrication of the crystalline material of the template. Specifically, higher germanium concentrations will enable lower temperatures to be utilized for formation of polycrystalline material within the template. In some embodiments, the germanium concentration within the SiGe-comprising template may be within a range of from about 5 atomic percent (at %) to about 95 at %; within a range of from about 10 at % to about 90 at %; within a range of from about 5 at % to about 50 at %, etc. In some embodiments, the relative amount of germanium within the SiGe-comprising template may be such that the crystalline material of the template may be formed at a temperature of less than or equal to about 500° C. The SiGe-comprising template may be heavily-doped in some embodiments, and may not be heavily-doped in other embodiments.

In some embodiments, it may be desirable for the template 14 to comprise germanium in the absence of silicon. Accordingly, in some embodiments the semiconductor material of the template 14 may consist essentially of, or consist of germanium. Such semiconductor material may be heavily-doped in some embodiments, and in other embodiments may not be heavily-doped.

A layer 17 of oxide is over the surface 15. The layer 17 may comprise, consist essentially of, or consist of one or both of silicon oxide and germanium oxide; and may form if surface 15 is exposed to air or some other source of oxygen. In some embodiments, the template 14 may be formed under conditions such that the surface 15 is never exposed to a source of oxygen, and accordingly the layer 17 may never be formed. However, to the extent that the layer 17 may form, it is desirable to remove such layer and thereby expose the surface 15 of the template 14. Accordingly, construction 10 is exposed to processing which removes the layer 17. Such processing transitions the construction 10 from the process stage “A” to a process stage “B”. The processing utilized to remove the layer 17 may be any suitable processing; including, for example, an etch utilizing fluorine-containing etchant (e.g., hydrofluoric acid). The etch may correspond to a wet clean, a gaseous clean, etc.

After the surface 15 is exposed, semiconductor material 18 is deposited along the surface 15. Such processing transitions the construction 10 from the process stage “B” to a process stage “C”. The removal of the layer 17 may be conducted within the same chamber utilized for the deposition, or within a different chamber.

The semiconductor material 18 may comprise any suitable composition; and in some embodiments may comprise, consist essentially of, or consist of silicon. The semiconductor material 18 may be referred to as a first semiconductor material to distinguish it from other semiconductor materials formed at subsequent process stages.

The deposition of the semiconductor material 18 may utilize any suitable method; and in some embodiments may utilize one or more of atomic layer deposition (ALD), chemical vapor deposition (CVD), plasma-enhanced chemical vapor deposition (PECVD), physical vapor deposition (PVD), and molecular beam epitaxy (MBE). For instance, in some example embodiments the deposition of the semiconductor material 18 may utilize CVD with a silicon precursor; a temperature within a range of from about 250° C. to about 500° C., and a pressure within a range of from about 1 Torr to about 1 atmosphere. The CVD may be plasma-enhanced in some embodiments. The plasma may or may not be remote relative to the deposited material 18.

The precursor utilized for the CVD may be any suitable precursor. For instance, if the CVD utilizes silicon precursor, such may include one or more of SiH, SiX and SiXH; where X represents halogen, and where the formulas indicate primary constituents rather than indicating specific stoichiometries. Example silicon precursors are monosilane, disilane, trisilane, neopentasilane and dichlorosilane.

The semiconductor material 18 may be formed under conditions which propagate crystalline properties from crystalline material along the surface 15 into the material 18 (i.e., may be epitaxially formed). Accordingly, the semiconductor material 18 may be at least partially crystalline. In some embodiments, the semiconductor material 18 may be substantially entirely crystalline throughout the entirety of its thickness (i.e., may be at least 95% crystalline, by volume). In other embodiments, the semiconductor material 18 may have a substantial amount of non-crystallinity (i.e., may comprise voids, amorphous regions, etc.). In some embodiments, the semiconductor material 18 may be formed to a thickness which exceeds its critical epitaxial thickness; and accordingly will have a lower region which is substantially entirely crystalline and an upper region which is less crystalline (i.e., more amorphous). The crystalline structure within material 18 may be related to the crystalline structure along the surface 15 of template 14. Accordingly, in embodiments in which the surface 15 is associated with a monocrystalline material, the semiconductor material 18 may also comprise a monocrystalline structure; and in embodiments in which the surface 15 is associated with polycrystalline material, the semiconductor material 18 may comprise a polycrystalline structure.

The semiconductor material 18 may be formed to any suitable thickness. However, in some embodiments it is desired to have substantial crystalline character throughout the majority of the thickness of the semiconductor material 18, and accordingly there is little benefit to exceeding the critical epitaxial thickness. In some embodiments, the semiconductor material 18 be formed to a thickness within a range of from about 5 angstroms (Å) to about 5000 Å.

The deposition of semiconductor material 18 may be conducted at any suitable temperature. In some embodiments, the semiconductor material 18 may be fabricated in an assembly which can withstand relatively high-temperature processing; and accordingly the deposition of the semiconductor material 18 be conducted at a temperature at or above about 600° C. In other embodiments, the semiconductor material 18 may be formed in assemblies which are sensitive to thermal processing, and may be formed at relatively low temperature; such as temperatures less than or equal to about 600° C., less than or equal to about 550° C., less than or equal to about 500° C., etc. The critical epitaxial thickness decreases with decreasing temperature, which is problematic for conventional processes. However, processing described herein may overcome such limitation and may be suitable for forming crystalline semiconductor material to thicknesses beyond the limiting critical epitaxial thicknesses of conventional processes, as will be discussed in more detail below.

Referring still to FIG. 1, the deposition of the first semiconductor material 18 is interrupted, and a second semiconductor material 20 is formed over the first semiconductor material 18 to transition the construction 10 to a process stage “D”. The deposition of the first semiconductor material 18 may be considered to be a first deposition process, and the semiconductor material 20 may be considered to be deposited in a second deposition process. In the shown embodiment, a surface of material 18 is etched, and the material 20 is deposited over such etched surface. The etching of the surface of material 18 may provide advantages; including, for example, removing excess material 18 which may have exceeded the critical epitaxial thickness of material 18 (i.e., removing regions of material 18 having less crystalline character then underlying regions), altering a surface (e.g., smoothing of the surface) of the first semiconductor material 18 to improve critical epitaxial thickness, etc.

The etching of material 18 may be conducted with any suitable etchant; and in some embodiments is conducted with halogen-containing etchant. The halogen-containing etchant may comprise chlorine (Cl); and in some embodiments may comprise one or both of diatomic chlorine (Cl₂) and hydrochloric acid (HCl).

The etchant may be provided together with the precursor utilized for deposition of the second semiconductor material 20, or may be provided sequentially relative to such precursor. In some embodiments, the precursor utilized for deposition of the second semiconductor material 20 comprises GeHₓ (where x is a number greater than 0), and the etchant is co-flowed with such precursor. In some embodiments, the precursor may be considered to form a germanium-containing seed material 20, and the etching and deposition of the germanium-containing seed material occur simultaneously.

The second semiconductor material 20 comprises a different composition than the first semiconductor material 18; and may, for example, comprise germanium. In some embodiments, the second semiconductor material 20 will be relatively pure in germanium (i.e., may consist essentially of, or consist of germanium). In other embodiments, the second semiconductor material 20 may comprise a mixture of germanium with another material; such as, for example, a mixture of germanium with silicon. The relative concentration of germanium within such mixture may be any suitable concentration; such as, for example, a concentration of at least about 5 at %, at least about 50 at %, etc. In some embodiments, the second semiconductor material 20 will comprise silicon and germanium (i.e., SiGe; where the formula indicates primary constituents rather than a specific stoichiometry), with the germanium concentration being within a range of from about 5 at % to about 95 at %.

In some embodiments, the material 20 may have a lower activation energy for epitaxial growth as compared to the material 18, and hence can act as a better crystalline surface for epitaxial growth of the material 18 as compared to the surface of a thick layer of the material 18 (where “thick layer” indicates a thickness approaching the critical epitaxial thickness of the material 18).

The deposition of the second semiconductor material 20 may utilize any suitable method; and in some embodiments may utilize one or more of ALD, CVD, PECVD, PVD, and MBE. For instance, in some example embodiments the deposition of the semiconductor material 20 may utilize CVD with one or both of a silicon precursor and a germanium precursor; a temperature within a range of from about 250° C. to about 500° C., and a pressure within a range of from about 1 Torr to about 1 atmosphere. The CVD may be plasma-enhanced in some embodiments. The plasma may or may not be remote relative to the deposited material 20. The silicon precursor(s) may be selected from the precursors described above relative to the semiconductor material 18; and the germanium precursor(s) may include one or more of GeH, GeX and GeXH; where X represents halogen, and where the formulas indicate primary constituents rather than indicating specific stoichiometries. Example germanium precursors are germane and digermane.

In some embodiments, the semiconductor material 20 may comprise a mixture of silicon and germanium; and the deposition of such semiconductor material may utilize one or both of germane and digermane in combination with dichlorosilane. In such embodiments, the etchant provided in addition to the deposition precursors may be a chlorine-containing etchant which includes chlorine released from the dichlorosilane.

The semiconductor material 20 may be formed under conditions which propagate crystalline properties from underlying crystalline material 18 into the material 20 (i.e., may be epitaxially formed). Accordingly, the semiconductor material 20 may be at least partially crystalline. In some embodiments, the semiconductor material 20 may be substantially entirely crystalline throughout the entirety of its thickness (i.e., may be at least 95% crystalline, by volume). In other embodiments, the semiconductor material 20 may have a substantial amount of non-crystallinity (i.e., may comprise voids, amorphous regions, etc.).

The processing stage “C” (i.e., the processing of forming the first semiconductor material 18) and the processing stage “D” (i.e., the processing of etching an upper surface of the first semiconductor material and forming the second semiconductor material 20) together form a Deposition Cycle. The deposition cycle may be repeated multiple times to form a semiconductor structure to a desired thickness. The process stage “E” shows an example semiconductor structure 22 which may result from multiple iterations of the Deposition Cycle.

The semiconductor structure 22 comprises first regions 24 comprising the first semiconductor material 18, and second regions 26 comprising the second semiconductor material 20. The first and second regions alternate with one another throughout the semiconductor structure 22. In some embodiments, the semiconductor structure 22 may be considered to correspond to a laminate of the alternating first regions 24 and second regions 26. Alternatively, the semiconductor structure 22 may be considered to be a vertically-extending structure comprising the first semiconductor material 18, and comprising stata of the second semiconductor material 20 extending horizontally through the first semiconductor material.

As discussed above, one or both of the semiconductor materials 18 and 20 may be at least partially crystalline. Accordingly, the semiconductor structure 22 may be at least partially crystalline. In some embodiments, the semiconductor structure 22 may be substantially entirely crystalline (i.e., may be at least 95% crystalline, by volume). The semiconductor structure 22 may be monocrystalline in some embodiments (e.g., if the template 14 is monocrystalline), and may be polycrystalline in other embodiments (e.g., if the template 14 is polycrystalline).

An advantage of intercalating the germanium-containing regions 26 into the semiconductor structure 22 is that such may reduce a temperature of formation of the overall semiconductor structure, while still enabling crystallinity to be maintained throughout an entirety of the structure. For instance, in some embodiments the entirety of the structure 22 may be formed utilizing deposition processes are conducted at temperatures of less than or equal to about 550° C., less than or equal to about 500° C., or even less than or equal to about 450° C. An increasing percentage of germanium within the overall structure 22 may advantageously enable lower temperatures to be utilized while still maintaining desired crystallinity throughout the structure. However, too much germanium may adversely impact device performance in some applications. Accordingly, it is desired to balance the overall amount of germanium within structure 22 in order to achieve low-temperature formation of a structure having desired crystallinity, while still maintaining desired properties (e.g., physical properties, electrical properties, chemical properties, etc.) suitable for an intended application.

The amount of germanium within the overall structure 22 may be tailored by adjusting the number of regions 26 provided throughout the structure, the composition of the regions 26 and/or the thicknesses of the regions 26. In some embodiments, an overall concentration of germanium within the semiconductor structure 22 will be less than about 10 at %, less than about 5 at %, etc. In some embodiments the first regions 24 comprise first thicknesses T₁, the second regions 26 comprise second thicknesses T₂, and the semiconductor structure 22 comprises an overall thickness T₃. A total of the second thicknesses T₂ may be less than or equal to about 10% of the overall thickness T₃, less than or equal to about 5% of the overall thickness, etc. Alternatively, the total of the second thicknesses T₂ may be less than or equal to about 10% of a total of the first thicknesses T₁, less than or equal to about 5% of the total of the first thicknesses, etc.

The thicknesses T₁, T₂ and T₃ may be any suitable thicknesses. In some embodiments, the thicknesses T₁ may be within a range of from about 5 Å to about 5000 Å. In some embodiments, the thicknesses T₂ may be within a range of from about 5 Å to about 100 Å, within a range of from about 5 Å to about 20 Å, etc. In some embodiments, the overall thickness T₃ may be within a range of from about 10 Å to about 20,000 Å, within a range of from about 200 Å to about 10,000 Å, etc.

The total number of germanium-containing regions 26 within the structure 22 may be any suitable number; including, for example, a number greater than or equal to about one; a number greater than or equal to about five; a number greater than or equal to about 10; a number greater than or equal to about 100; and number greater than or equal to about 1000, etc.

In the shown embodiment, the semiconductor structure 22 comprises two alternating regions of different composition relative to one another. In other embodiments, the semiconductor structure may comprise more than two different regions. For instance, the Deposition Cycle may form three or more regions of different composition relative to one another. In some embodiments, such regions may comprise silicon-containing regions analogous to the regions 24; one type of germanium-containing region analogous to some of the regions 26 and having a first concentration of germanium; and another type of germanium-containing region analogous to others of the regions 26 and having another concentration of germanium.

In some embodiments, it may be desired to anneal the semiconductor materials 18 and 20 after the formation of structure 22. The anneal may be conducted at any suitable temperature for any suitable duration.

In the shown embodiment of FIG. 1, the germanium-containing regions 26 are regularly spaced from one another, and are of about the same thickness as one another (with the term “about the same thickness” meaning the same thickness to within reasonable tolerances of fabrication and measurement). Such may result from the deposition of the semiconductor material 18 within the Deposition Cycle being intermittently interrupted by the deposition of the semiconductor material 20, with the interruptions being spaced from one another by substantially regular intervals (with the term “substantially regular” meaning regular to within reasonable tolerances), and being conducted for substantially the same duration as one another (with the term “substantially the same duration” meaning the same duration to within reasonable tolerances). In other embodiments, at least some of the interruptions utilized to form the semiconductor material 20 may be spaced from one another by different intervals than others of the interruptions; and/or at least one of the interruptions may be conducted for a substantially different duration than another of the interruptions. Accordingly, the germanium-containing regions 26 may not all be regularly spaced from one another, and/or may not all be about the same thickness as one another.

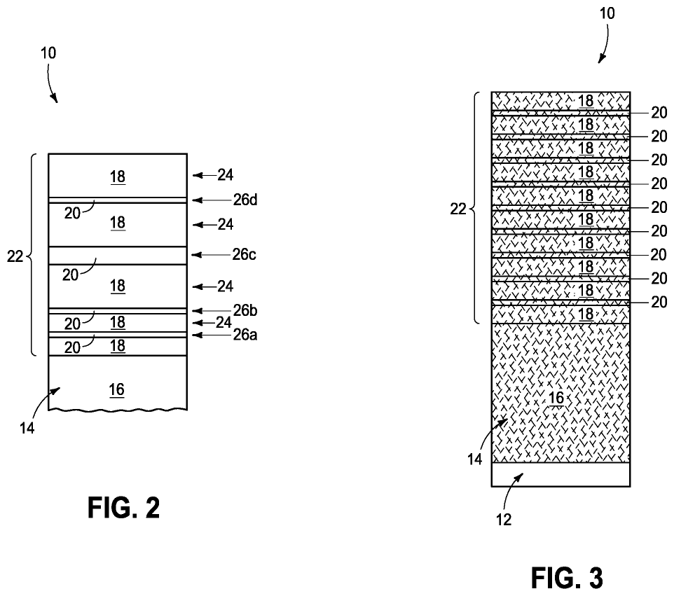

FIG. 2 shows a portion of a construction 10 analogous to that shown at a process stage “E” of FIG. 1. However, the second regions 26 (i.e., the germanium-containing regions) are not all spaced from one another by regular intervals. Instead, a first neighboring pair of the second regions (with such first neighboring pair comprising second regions labeled as 26a and 26b) is spaced from one another by a different distance than is a second neighboring pair of the second regions (with such second neighboring pair comprising second regions labeled as 26c and 26d). Also, all of the regions 26 are not the same thickness as one another. Instead, the region 26c is shown to be thicker than the other regions 26. In some embodiments, the region 26c may be considered to be of a substantially different thickness than the other regions; with the term “substantially different thickness” meaning a difference in thickness outside of the reasonable tolerances of a fabrication process.

As discussed above, the semiconductor structure 22 may be at least partially crystalline, and may have a crystalline configuration which propagates from crystallinity of the template 14. FIG. 3 shows a construction 10 analogous to that shown at a process stage “E” of FIG. 1, and shows crystallinity (represented by dashed lines) extending through the template 14 and the semiconductor structure 22. The dashed lines may be considered to represent the lattice of a monocrystalline material, the grains of a polycrystalline material, etc.

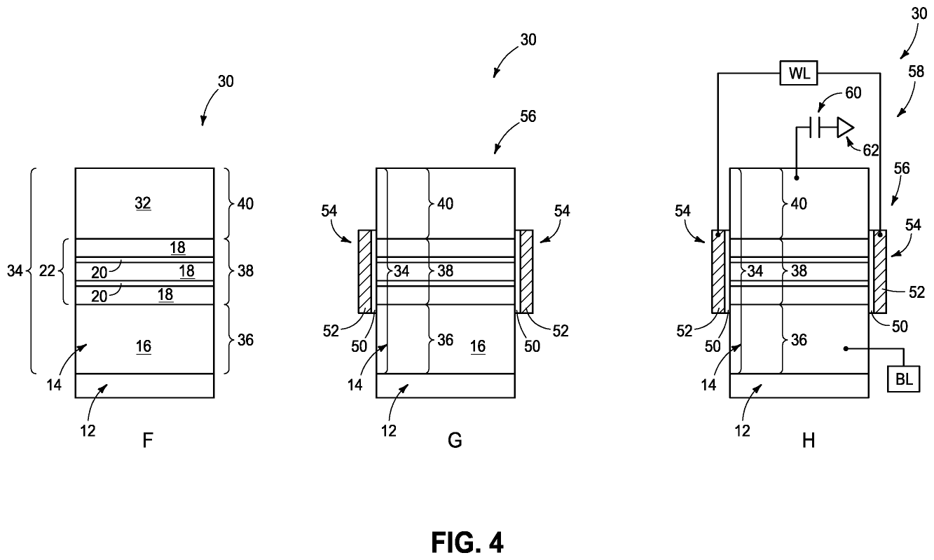

The semiconductor structure 22 may be utilized in any suitable devices. FIG. 4 illustrates an application in which the semiconductor structure is incorporated into a transistor.

A process stage F at the left side of FIG. 4 shows a construction 30 having the semiconductor construction 22 formed over a template 14, and having semiconductor material 32 formed over the construction 22. In some embodiments, the template 14, semiconductor structure 22, and semiconductor material 32 may be considered together to correspond to an active region 34 suitable for incorporation into a transistor. Such active region comprises a first portion (or first segment) 36 corresponding to the template 14, a second portion (or second segment) 38 corresponding to the semiconductor structure 22, and a third portion (or third segment) 40 corresponding to the semiconductor material 32. The portions 36 and 40 may be conductively-doped so that they are suitable for utilization as source/drain regions of the transistor (i.e., may be heavily doped with n-type dopant or p-type dopant), and the portion 38 may be appropriately doped to be suitable for utilization as a channel region of the transistor; i.e., may be may be either undoped (i.e. intrinsically doped), or lightly doped (i.e., doped to less than or equal to 10¹⁸ atoms/cm³ with conductivity-enhancing dopant).

The processing stage “G” of FIG. 4 shows insulative material 50 formed adjacent the segment 38 of the active region 34, and shows conductive material 52 formed adjacent the insulative material 50.

The insulative material 50 may comprise any suitable composition(s), and in some embodiments may comprise, consist essentially of, or consist of silicon oxide.

The conductive material 52 may comprise any suitable composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

The conductive material 52 forms a transistor gate 54 along the segment 38, with such transistor gate being spaced from the segment 38 by the intervening insulative material 50 (which may be referred to as gate dielectric material). A transistor 56 comprises the transistor gate 54 together with the active region 34.

The transistor 56 is a vertical transistor in that the active region 34 of such transistor extends vertically from the base 12.

The transistor 56 may be utilized in a memory array. For instance, the process stage “H” shows the transistor 56 incorporated into a memory cell 58. The transistor gate 54 is coupled with a wordline WL, the source/drain region 36 is coupled with a bitline BL, and the source/drain region 40 is coupled with a capacitor 60. The capacitor has a node coupled with a reference voltage 62. Such reference voltage may correspond to ground, or to any other suitable voltage.

The memory cell 58 may be representative of a large number of substantially identical memory cells formed across a memory array; with the term “substantially identical” meaning identical to within reasonable tolerances of fabrication and measurement.

The transistor 56 of FIG. 4 comprises the structure 22 (i.e., the structure having germanium-containing levels interspersed between the silicon-containing levels) utilized as a channel region. Such may be advantageous in that it is desired to have crystallinity throughout a transistor active region (e.g., the active region 34 of FIG. 4), and it is often found to be difficult to achieve crystallinity at low processing temperatures for semiconductor material having a low concentration of dopant therein (e.g., a channel region). In contrast, semiconductor regions having high concentrations of dopant (e.g., source/drain regions) may be formed to have suitable crystallinity therein by utilizing low processing temperatures, even when utilizing conventional methods. It may be desired to incorporate the germanium-containing layers only into the portion of the active region 34 which will most benefit from having such layers therein (e.g., the lightly-doped channel region) in order to minimize an amount of germanium within the active region. Specifically, too much germanium within a transistor active region may cause a transistor device to operate outside of desired parameters. However, in some embodiments it may be suitable to incorporate germanium within one or both of the source/drain regions of the transistor. In such embodiments, the structure 22 may extend across one or both of the source/drain regions 36 and 40, in addition to extending across the channel region 38.

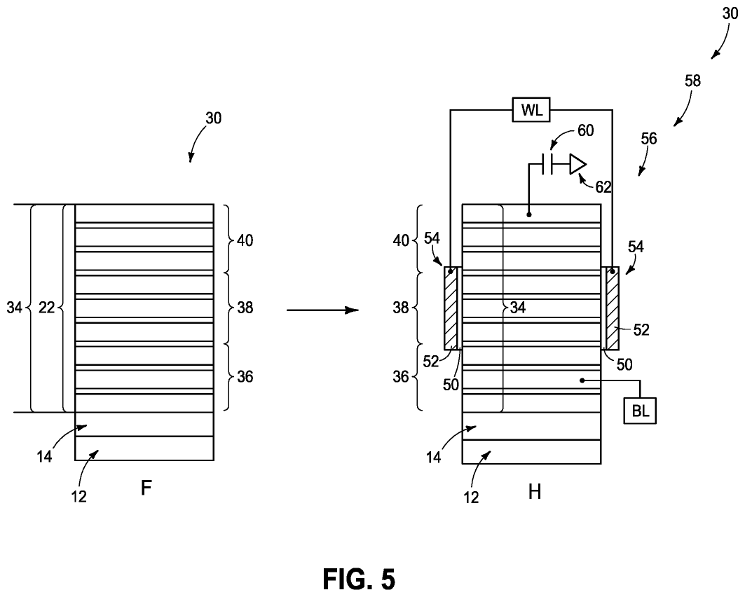

FIG. 5 shows an example construction 30 analogous to the construction of FIG. 4, but comprising the structure 22 extending across an entirety of the active region 34. The left side of FIG. 5 shows the active region 34 in isolation from the rest of a transistor (i.e., shows a process stage analogous to the process stage F of FIG. 4), and the right side of FIG. 5 shows the active region 34 incorporated into a transistor 56, which in turn is incorporated into a memory cell 58 (i.e., shows a process stage analogous to the process stage H of FIG. 4).

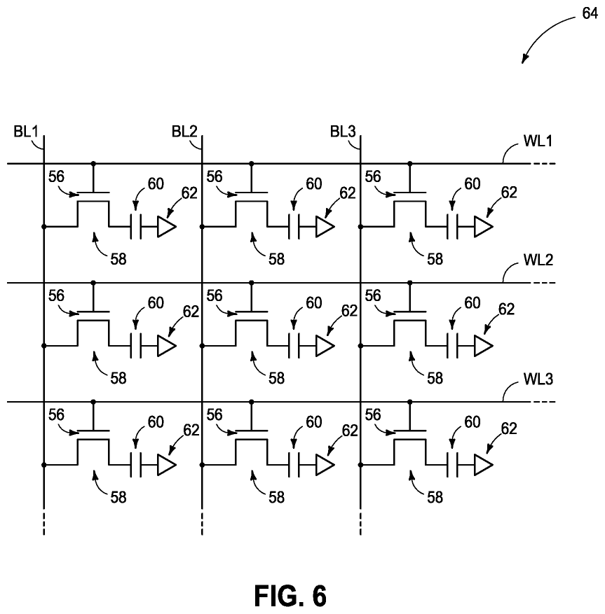

The memory cells 58 of FIGS. 4 and 5 may be utilized in DRAM arrays. An example memory array 64 is described with reference to FIG. 6. The memory array comprises a plurality of wordlines (represented by the wordlines WL1, WL2 and WL3) extending along rows of the array, and comprises a plurality of bitlines (represented by the bitlines BL1, BL2 and BL3) extending along columns of the array. The memory array comprises a plurality of substantially identical memory cells 58; with each of the memory cells comprising a transistor 56 in combination with a capacitor 60.

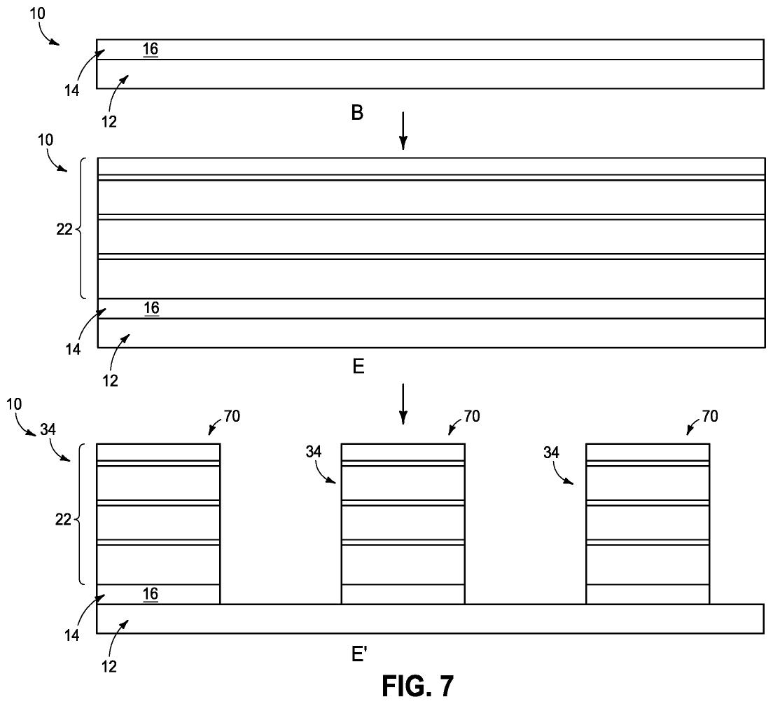

In some embodiments, the semiconductor material 16 of the above-described embodiments may be formed as an expanse, the semiconductor structure 22 may be deposited over such expanse, and then the semiconductor structure 22 may be patterned into desired configurations. For instance, FIG. 7 shows the construction 10 of FIG. 1 in an embodiment in which the semiconductor material 16 of the template 14 is initially configured as a large expanse. An uppermost process stage of FIG. 7 is analogous to the process stage B of FIG. 1. The next process stage of FIG. 7 is analogous to the process stage E of FIG. 1, and has the semiconductor structure 22 formed over the template 14. The final process stage shown in FIG. 7 is a process stage E′ in which the semiconductor structure 22 is patterned into structures 70 configured as transistor active regions 34.

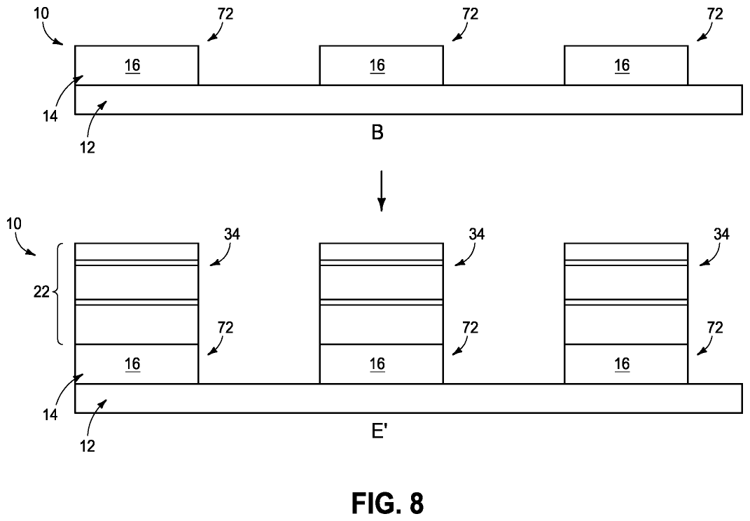

In some embodiments, the semiconductor material 16 of the above-described embodiments may be patterned into spaced-apart pads, and then the semiconductor structures 22 may be selectively deposited onto such pads. For instance, FIG. 8 shows the construction 10 of FIG. 1 in an embodiment in which the semiconductor material of the template is patterned into pads. An uppermost process stage of FIG. 8 is analogous to the process stage B of FIG. 1, and shows the semiconductor material 16 of the template 14 patterned into pads 72 supported by the base 12. The next process stage of FIG. 8 is analogous to the process stage E of FIG. 1, and has the semiconductor structures 22 deposited over the template 14. The semiconductor structures 22 are selectively deposited onto the material 16 relative to the base 12.

The semiconductor structures 22 described herein may be utilized in any suitable applications. Also, the transistors described herein may be utilized in any suitable applications. Although the transistors are specifically shown being utilized in DRAM memory cells, it is to be understood that the transistors may be utilized in other applications; such as, for example, logic, sensors, and/or other memory besides the illustrated DRAM.

The assemblies and structures discussed above may be utilized within integrated circuits (with the term “integrated circuit” meaning an electronic circuit supported by a semiconductor substrate); and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

Unless specified otherwise, the various materials, substances, compositions, etc. described herein may be formed with any suitable methodologies, either now known or yet to be developed, including, for example, atomic layer deposition (ALD), chemical vapor deposition (CVD), physical vapor deposition (PVD), plasma-based methods (e.g., plasma-enhanced CVD), etc.

The terms “dielectric” and “insulative” may be utilized to describe materials having insulative electrical properties. The terms are considered synonymous in this disclosure. The utilization of the term “dielectric” in some instances, and the term “insulative” (or “electrically insulative”) in other instances, may be to provide language variation within this disclosure to simplify antecedent basis within the claims that follow, and is not utilized to indicate any significant chemical or electrical differences.

The particular orientation of the various embodiments in the drawings is for illustrative purposes only, and the embodiments may be rotated relative to the shown orientations in some applications. The descriptions provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections, unless indicated otherwise, in order to simplify the drawings.

When a structure is referred to above as being “on”, “adjacent” or “against” another structure, it can be directly on the other structure or intervening structures may also be present. In contrast, when a structure is referred to as being “directly on”, “directly adjacent” or “directly against” another structure, there are no intervening structures present.

Structures (e.g., layers, materials, etc.) may be referred to as “extending vertically” to indicate that the structures generally extend upwardly from an underlying base (e.g., substrate). The vertically-extending structures may extend substantially orthogonally relative to an upper surface of the base, or not.

Some embodiments include a method of forming a semiconductor structure. A first semiconductor material is deposited with a first deposition process. The first deposition process is intermittently interrupted to etch a surface of the deposited first semiconductor material and to deposit a second semiconductor material with a second deposition process. The first and second semiconductor materials are compositionally different from one another. The first deposition process forms first regions of the semiconductor structure and the second deposition process forms second regions of the semiconductor structure, with the first regions comprising the first semiconductor material and with the second regions comprising the second semiconductor material. The first and second deposition processes together form the semiconductor structure to comprise a laminate having the first regions alternating with the second regions.

Some embodiments include a method of forming a semiconductor structure corresponding to at least a portion of an active region of a transistor. A first semiconductor material is deposited with a first deposition process. The first semiconductor material comprises silicon. The first deposition process is intermittently interrupted to etch a surface of the deposited first semiconductor material and to deposit a second semiconductor material with a second deposition process. The second semiconductor material comprises germanium. The semiconductor structure is at least partially crystalline.

Some embodiments include a semiconductor structure which includes a laminate having first regions alternating with second regions. The first regions include first semiconductor material which consists essentially of silicon, and the second regions include second semiconductor material which comprises germanium.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1-35. (canceled)

36. A semiconductor structure comprising:
a laminate having first regions alternating with second regions; the first regions comprising first semiconductor material which consists essentially of silicon, and the second regions comprising second semiconductor material which comprises germanium; and
a channel region comprised by the laminate.

37. The semiconductor structure of claim 36 wherein the second semiconductor material consists essentially of the germanium.

38. The semiconductor structure of claim 36 wherein the second semiconductor material comprises a mixture of the germanium with silicon.

39. The semiconductor structure of claim 38 wherein a germanium concentration within said mixture is at least about 5 atomic percent.

40. The semiconductor structure of claim 38 wherein a germanium concentration within said mixture is at least about 50 atomic percent.

41. The semiconductor structure of claim 38 wherein a germanium concentration within said mixture is within a range of from about 5 atomic percent to about 95 atomic percent.

42. The semiconductor structure of claim 36 wherein there are multiple of the second regions; with all of the second regions being spaced from one another by a substantially common distance, and being of about a same thickness as one another.

43. The semiconductor structure of claim 36 wherein there are multiple of the second regions; with a first neighboring pair of the second regions being spaced from one another by a different distance than a second neighboring pair of the second regions.

44. The semiconductor structure of claim 36 wherein there are multiple of the second regions; with one of the second regions being of a substantially different thickness than another of the second regions.

45. The semiconductor structure of claim 36 wherein the first regions comprise first thicknesses and the second regions comprise second thicknesses; and wherein a total of the second thicknesses is less than or equal to about 10% of a total of the first thicknesses.

46. The semiconductor structure of claim 45 wherein the total of the second thicknesses is less than or equal to about 5% of the total of the first thicknesses.

47. The semiconductor structure of claim 45 wherein the second thicknesses are within a range of from about 5 Å to about 100 Å.

48. The semiconductor structure of claim 45 wherein the second thicknesses are within a range of from about 5 Å to about 20 Å.

49. The semiconductor structure of claim 36 comprising at least a portion of an active region of a transistor.

50. The semiconductor structure of claim 49 wherein said active region includes a first segment comprising a first source/drain region, a second segment comprising a channel region, and a third segment comprising a second source/drain region; the channel region being between the first and second source/drain regions; and wherein the semiconductor structure includes the second segment of the active region.

51. The semiconductor structure of claim 50 wherein the semiconductor structure also includes the third segment of the active region.

52. The semiconductor structure of claim 51 wherein the semiconductor structure also includes the first segment of the active region.

53. The semiconductor structure of claim 36 wherein at least one of the first and second regions are polycrystalline.

54. The semiconductor structure of claim 36 wherein both of the first and second regions are polycrystalline.

55. The semiconductor structure of claim 36 wherein only one of the first and second regions is polycrystalline.

56. The semiconductor structure of claim 36 wherein the laminate is over a source/drain region.

57. The semiconductor structure of claim 56 wherein the source/drain region is electrically coupled to a bitline.

58. The semiconductor structure of claim 36 wherein the laminate is between a pair of source/drain regions.

59. The semiconductor structure of claim 58 wherein one of the source/drain regions is electrically coupled to a capacitor.

60. The semiconductor structure of claim 58 wherein one of the source/drain regions is electrically coupled to a bitline.

61. The semiconductor structure of claim 60 wherein the other of the source/drain regions is electrically coupled to a capacitor.

62. The semiconductor structure of claim 36 wherein the laminate is adjacent a gate dielectric.

63. The semiconductor structure of claim 62 wherein the laminate is against the gate dielectric and adjacent a gate structure.

64. The semiconductor structure of claim 63 wherein the gate structure is electrically coupled to a wordline.

65. The semiconductor structure of claim 36 wherein the laminate is adjacent a pair of gate structures, and the pair of gate structures are electrically coupled to a wordline.

66. The semiconductor structure of claim 36 wherein the laminate establishes a portion of one source/drain region.

67. A semiconductor structure comprising:
a laminate having first regions alternating with second regions; the first regions comprising first semiconductor material which consists essentially of silicon, and the second regions comprising second semiconductor material which comprises germanium; and
a transistor, the laminate comprising a portion of the transistor.

68. The semiconductor structure of claim 67 wherein the portion is a channel region.

69. The semiconductor structure of claim 67 wherein the portion is one source/drain region.

70. The semiconductor structure of claim 67 wherein the portion is a channel region and one source/drain region.
